(19) United States
(12) Patent Application Publication
(10) Pub. No.: US 2011/0148461 A1
(43) Pub. Date: Jun. 23, 2011

(54) METHOD AND DEVICE FOR GENERATING AND SUPPLYING CONFIGURATION DATA FOR AND/OR TO A PROGRAMMABLE, INTEGRATED LOGIC CIRCUIT

(76) Inventor: Sébastien Leger, Waiblingen (DE)

(21) Appl. No.: 12/440,561

(22) PCT Filed: Jul. 20, 2007
(86) PCT No.: PCT/EP2007/006738

§ 371 Date: Sep. 14, 2009

(30) Foreign Application Priority Data
Sep. 26, 2006 (DE) 10 2006 045 372.7

(51) Int. Cl. H03K 19/177

(52) U.S. Cl. 326/39

(57) ABSTRACT

In a method for the supply of encoded configuration data (14) to a programmable, integrated logic circuit (4), un-encoded configuration data (12) comprising an algorithm (20) are initially supplied to the logic circuit (4). The encoded configuration data (14) are loaded into the logic circuit (4) and, by means of the algorithm (20) and a key (34), which is supplied to the logic circuit (4) logic-circuit-externally and separately from the encoded configuration data (14) and from the un-encoded configuration data (12), decoded for the activation of the algorithm (20) and stored logic-circuit-internally. Moreover, a device (2) for the implementation of the method and method for generating the configuration data (12, 14) provided for the programmable, integrated logic circuit (4) are specified.

The invention relates to a method for supplying encoded configuration data to a programmable, integrated logic circuit, to a device for the implementation of the method, to a method for generating configuration data provided for the logic circuit and a digital storage medium, a computer program and a computer-software product for the execution of the method.

One conventional implementation of a system for controlling, for example, a unit or a computer takes place through a corresponding configuration of a freely-programmable logic circuit, which is also referred to as an FPGA. FPGA is an abbreviation for the English term “Field Programmable Gate Array”. An FPGA is an electronic circuit, of which the switching functions are obtained via configuration, that is to say, by programming switching cells and programmable connections between these switching cells.

An FPGA configuration is a standard method for initialising devices or components. It is conventional to realise processor elements and digital peripheral components with FPGAs. The configuration of the FPGA, in particular an FPGA based on RAM, with configuration data is loaded from a memory external to the FPGA into special memory cells of the FPGA. Many FPGA types additionally allow the reading and the re-writing of the configuration; also only of parts of the FPGA. Such a re-writing of the configuration is referred to as a re-configuration; in the case of parts of the FPGAs, as a partial reconfiguration. In the case of the partial reconfiguration, the FPGA is therefore partially re-configured, without touching the parts of the FPGA not affected by the reconfiguration.

The FPGA configuration data describe the internal switching functions, that is to say, the internal design of the FPGA. In particular, in the case of an FPGA based on RAM, which represents the largest family of all FPGA types, the FPGA configuration data are stored in a memory external to the FPGA. As a result, there is the risk of undesired access to the configuration data, since it is possible to infer the internal design of the FPGA, for example, on the basis of the configuration data, by means of reverse engineering.

Accordingly, it is conventional to store the configuration data in an encoded manner in the external memory and also to protect them from undesired access when loading the configuration data from the external memory into the FPGA.

The specification EP 1 124 330 A2 discloses a method for protecting configuration data from undesired access. In this context, according to the method disclosed in EP 1 124 330 A2, the configuration data are loaded from externally into the FPGA, decoded in the FPGA by means of a decoding unit and a configuration unit and stored in an FPGA-internal configuration memory device. A key matching a decoding algorithm required for the decoding of the configuration data for the activation of the decoding unit is provided by an FPGA-internal random generator with a random algorithm and stored in a key memory device.

However, with the method according to the specification EP 1 124 330 A2, the random algorithm implemented in the FPGA is known to the hardware manufacturer of the FPGA. Accordingly, by generating the key with the assistance of the random algorithm known to the manufacturer, the manufacturer can gain access to encoded configuration data, which have been programmed by a software manufacturer, decode the latter and utilise them externally.

The invention is based upon the object of providing a method, a device and a digital storage medium, a computer program and a computer-software product, with which encoded configuration data are supplied in a particularly reliable manner and at a particularly low cost to a programmable, integrated logic circuit, and of indicating a method and a digital storage medium, a computer program and a computer-software product, with which configuration data provided for the logic circuit can be generated in a technically, particularly simple and efficient manner.

With regard to the method, the object is achieved according to the invention by the features of claims 1 and 16. Advantageous further developments form the subject matter of the dependent claims referring back to the latter.

With regard to the device, the object is achieved according to the invention by the features of claim 7. Advantageous further developments form the subject matter of the dependent claims referring back to the latter.

With regard to the digital storage medium, the computer programs and the computer-software product, the object is achieved according to the invention by the features of claims 18 to 21.

Accordingly, the method of the invention for supplying encoded configuration data to a programmable, integrated logic circuit initially comprises a method step, wherein the un-encoded configuration data, which include an algorithm, are loaded into the logic circuit. Following this, the encoded configuration data, which are provided for the at least partial configuration of the logic circuit, are transferred into the logic circuit and decoded by means of the algorithm and a key, which is used for the activation of the algorithm. The decoded configuration data are stored in the logic circuit. The supply of the key to the logic circuit is implemented separately from the encoded configuration data and separately from the un-encoded configuration data.

The device according to the invention for the implementation of the method for supplying the encoded configuration data to the logic circuit provides a loading interface, across which the un-encoded configuration data and the encoded configuration data are loaded into the logic circuit, and a logic-circuit-external key interface, with which a connection from outside the logic circuit to inside the logic circuit is established for the separate supply of the key. Furthermore, the device according to the invention provides a logic-circuit-internal interface, across which the encoded configuration data decoded after decoding are stored within the logic circuit, in particular, for the partial reconfiguration of the logic circuit.

The other method according to the invention for generating the configuration data provided for the programmable, integrated logic circuit initially comprises the provision of the configuration data in a generating module provided for the purpose. In a subsequent method step, the configuration data are subdivided into configuration data to be encoded, which are provided for the configuration of the logic circuit, and un-encoded configuration data, which include the algorithm for the encoding and for the decoding of the configuration data to be encoded. Additionally, a key matching the algorithm for the activation of the algorithm for the encoding and the decoding of the configuration data to be encoded is generated. By activating the algorithm by means of the key, the configuration data to be encoded are encoded, and the key is stored separately from the un-encoded configuration data including the algorithm and from the encoded configuration data, externally from the logic circuit.

The advantages achieved with the invention consist, in particular, in that the encoded configuration data comprising the internal design of the logic circuit are protected particularly securely and reliably from external and/or undesired access not only with regard to the final customer, but also with regard to the manufacturer of the logic-circuit hardware. Accordingly, neither the algorithm nor the key matching the algorithm is known to the manufacturer of the logic-circuit hardware. Furthermore, a storage of the key and/or of the algorithm logic-circuit-internally is not necessary. Moreover, in the case of a risk of undesired access to the decoding of the encoded configuration data, the key merely needs to be removed from the logic circuit and/or deleted without damaging or destroying the logic circuit as a whole.

Furthermore, a probability of an undesired decoding of the encoded configuration data by an external user on the basis of the separate storage of the key and of the un-encoded configuration data, which include the algorithm, is particularly slight. Since the encoded configuration data are encoded logic-circuit-internally, the probability of gaining access to the decoded data, which are associated with the encoded configuration data, during the loading of the encoded configuration data into the logic circuit, is particularly slight. Beyond this, the methods according to the invention are technically particularly simple to execute, and the device according to the invention can be realised at a particularly low cost.

According to an advantageous embodiment, the un-encoded configuration data comprise start-up instructions, which are initially loaded into the logic circuit, so that the logic circuit is expediently booted at a time before the supply of the algorithm and before the supply of the encoded configuration data.

In an expedient further development, the un-encoded configuration data comprise key instructions, which are preferably used, after the supply of the un-encoded configuration data to the logic circuit, to configure the logic-circuit-external key interface, across which the key is expediently supplied to the logic circuit.

In order to minimise the probability of an undesired access to the encoded configuration data at a time before and/or after the decoding, the logic-circuit-external key interface is preferably connected only during the loading of the key into the logic circuit. According to an advantageous embodiment, the key interface is connected only for the period of the actual supply of the key, so that an undesired access to the encoded configuration data during the decoding of the encoded configuration data is also prevented.

In order to protect the configuration data decoded in the logic circuit in a particularly reliable manner from an undesired access via the logic-circuit-external key interface, via the loading interface and/or another interface, which establishes a connection between the outside and the inside of the logic circuit, the decoded configuration data are preferably stored in the logic circuit via a logic-circuit-internal interface, which offers particularly reliable protection from access from outside the logic circuit. The logic-circuit-internal interface is configured via commands, which are expediently deposited in the un-encoded configuration data.

According to an advantageous embodiment, a configuration memory device for the storage of the un-encoded configuration data and/or encoded configuration data is provided logic-circuit-externally. By preference, the configuration memory device is provided physically separately from the logic circuit. The configuration memory device is expediently designed as a tabular memory, preferably as a programmable read-only memory (PROM). According to an advantageous embodiment, the encoded configuration data and the un-encoded configuration data are stored separately in physically separate configuration memories.

According to an expedient further development, the logic circuit is designed as a freely programmable logic circuit (FPGA).

In order to store the key logic-circuit-externally, physically separated from the configuration data, a key memory device is expediently provided, which can preferably be coupled to the logic-circuit-external key interface for the loading of the key into the logic circuit. In order in the case of a risk of an undesired access to the key and/or to the logic circuit during the supply of the key for the activation of the algorithm, the key memory device is designed to be deletable. For this purpose, the key memory device preferably provides a delete function, in particular, a rapid-delete function for the deletion of the key. The delete function can expediently be activated manually and/or automatically via the logic circuit in the case of a risk of an undesired access to the key and/or to the configuration data to be decoded or already at least partially decoded, which is disposed in the logic circuit.

In an expedient further development, the key for encoding the configuration data to be encoded differs from the key for decoding the encoded configuration data.

An exemplary embodiment of the invention is explained in greater detail below with reference to the drawings. The drawings are as follows:

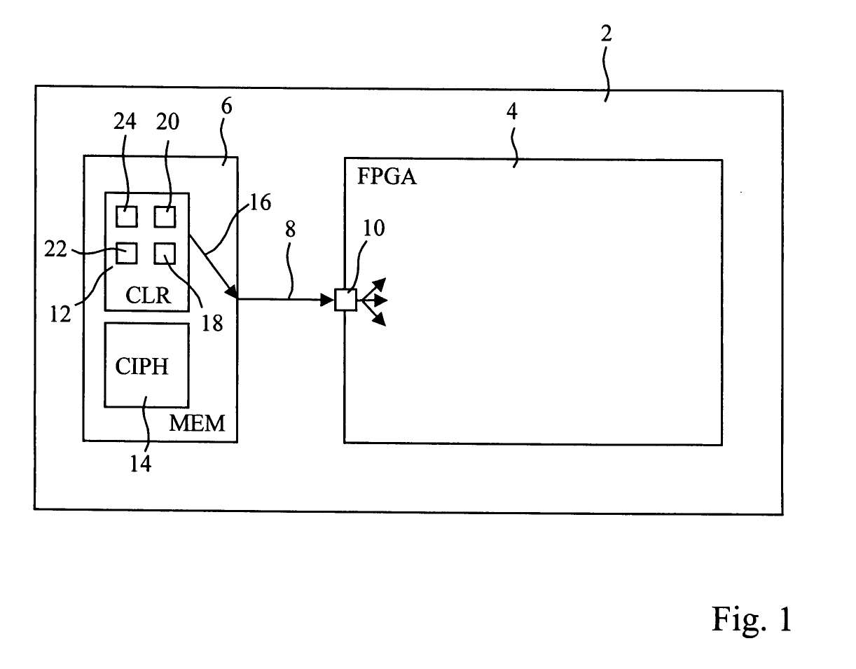

FIG. 1 shows a schematic presentation of the device with a logic circuit, wherein the un-encoded configuration data are loaded into the logic circuit from a configuration memory device comprising the un-encoded configuration data and encoded configuration data;

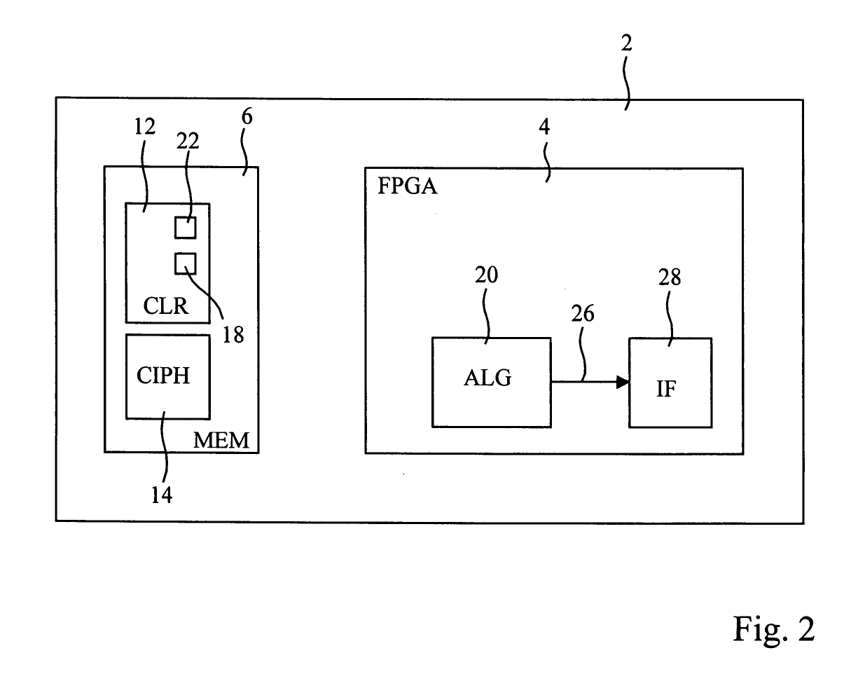

FIG. 2 shows a schematic presentation of the device according to FIG. 1, with the logic circuit comprising an algorithm for decoding the encoded configuration data and a logic-circuit-internal interface;

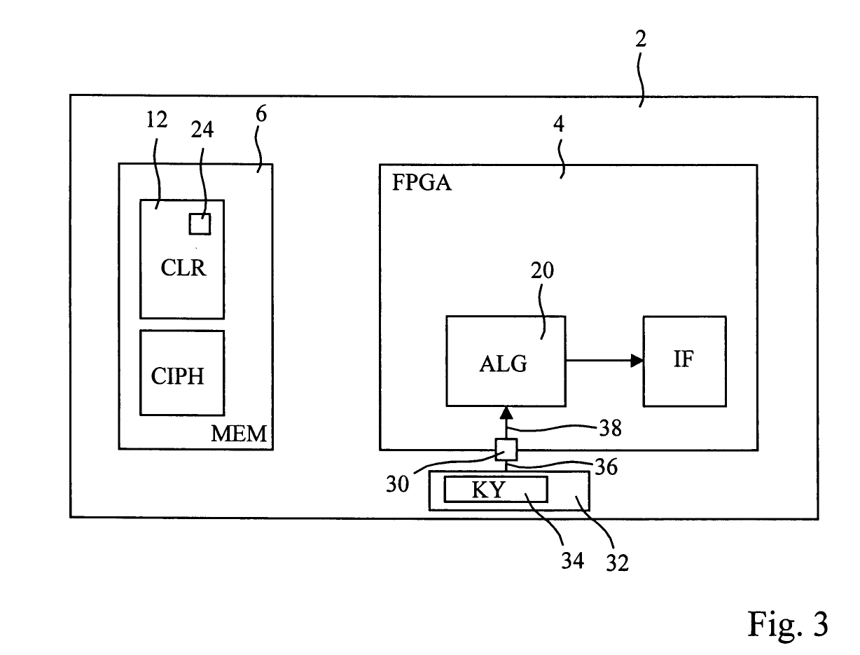

FIG. 3 shows a schematic presentation of the device according to FIG. 1 with the logic circuit with a logic-circuit-external key interface, across which a key for the activation of the algorithm is loaded into the logic circuit;

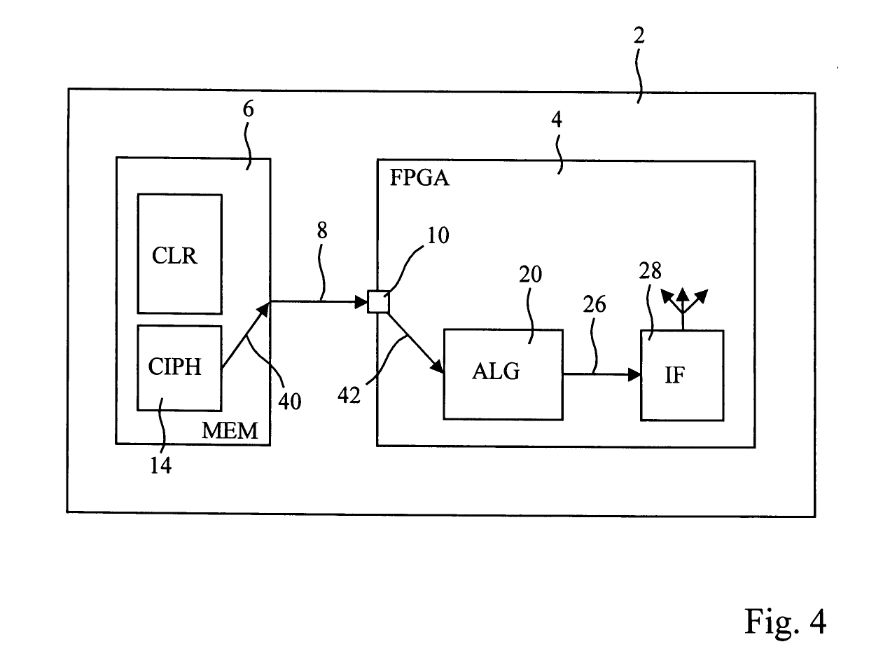

FIG. 4 shows a schematic presentation of the device according to FIG. 1 with the logic circuit, wherein the encoded configuration data are loaded from the configuration memory device into the logic circuit, decoded by means of the algorithm activated with the key and stored via the logic-circuit-internal interface in the latter for the partial configuration of the logic circuit;

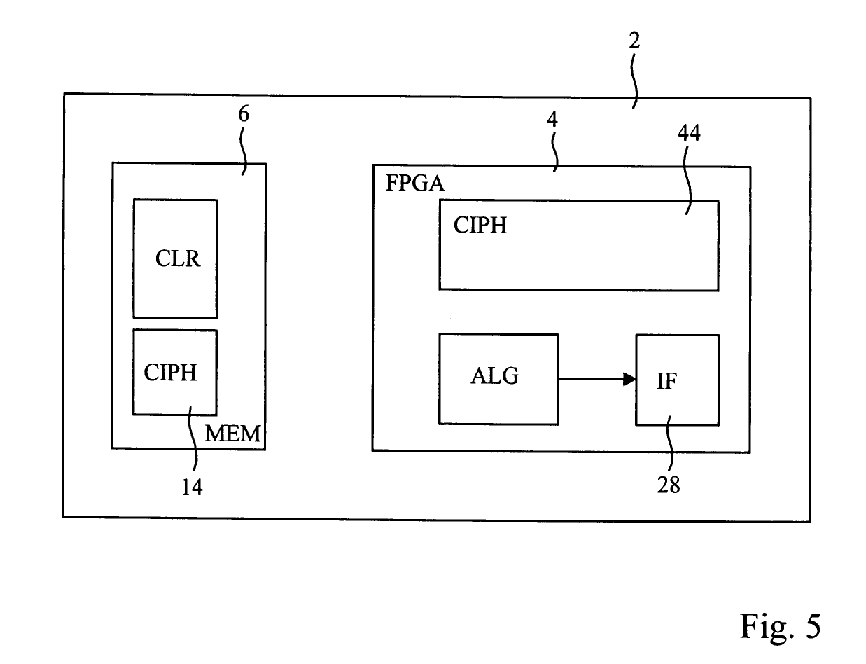

FIG. 5 shows a schematic presentation of the device according to FIG. 1 with the logic circuit, wherein the decoded configuration data are stored in the logic circuit;

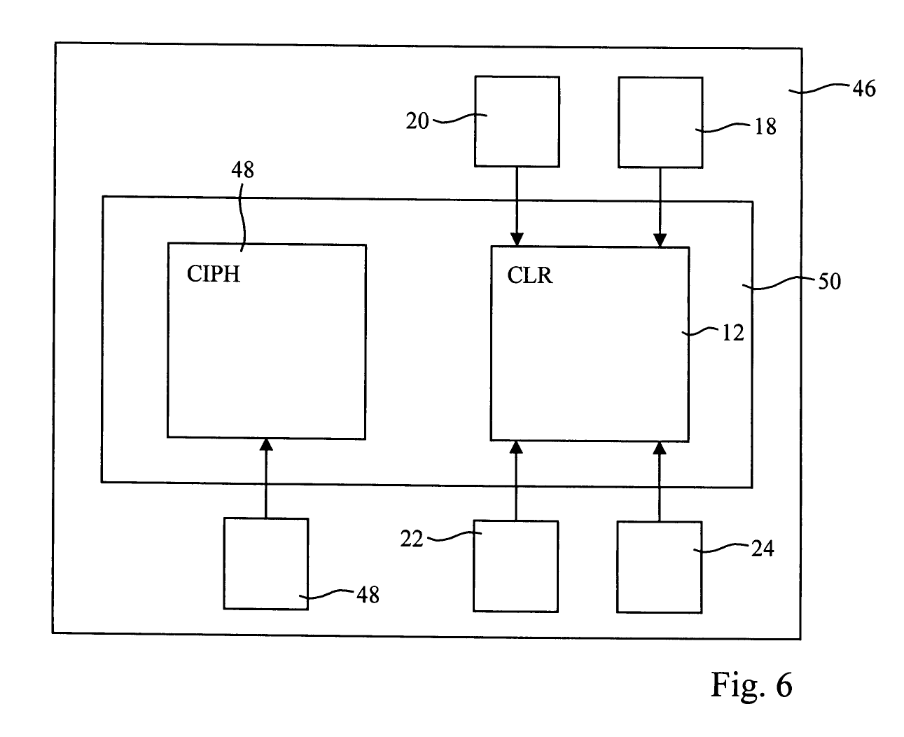

FIG. 6 shows a schematic presentation of a generating module for the generation of configuration data provided for the logic circuit and for the storage of the configuration data in a configuration data-record;

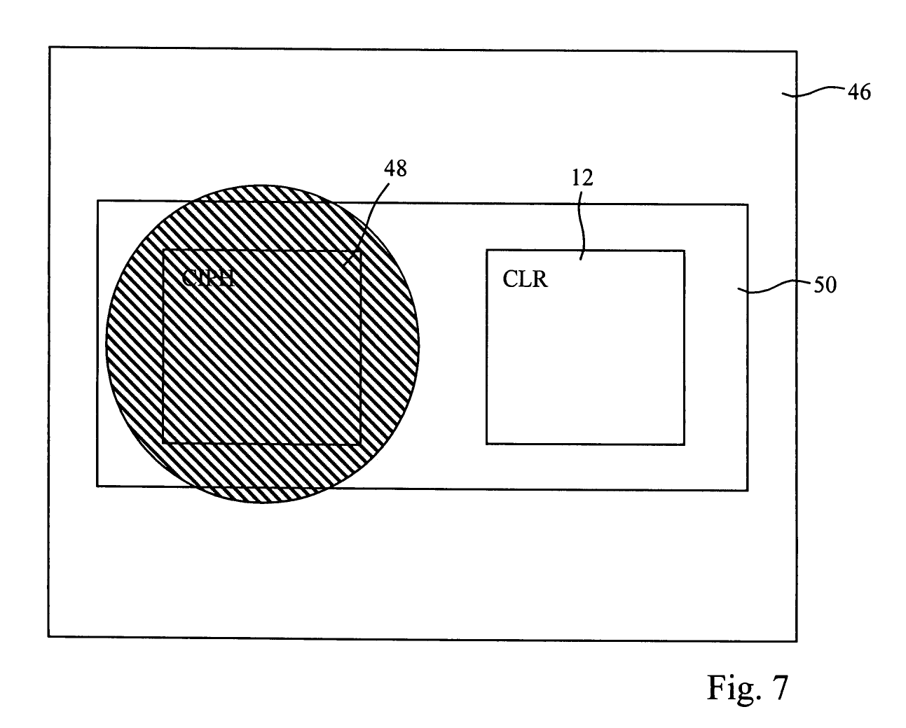

FIG. 7 shows a schematic presentation of the generating module according to FIG. 6, wherein the configuration data are separated into un-encoded configuration data and the configuration data to be encoded;

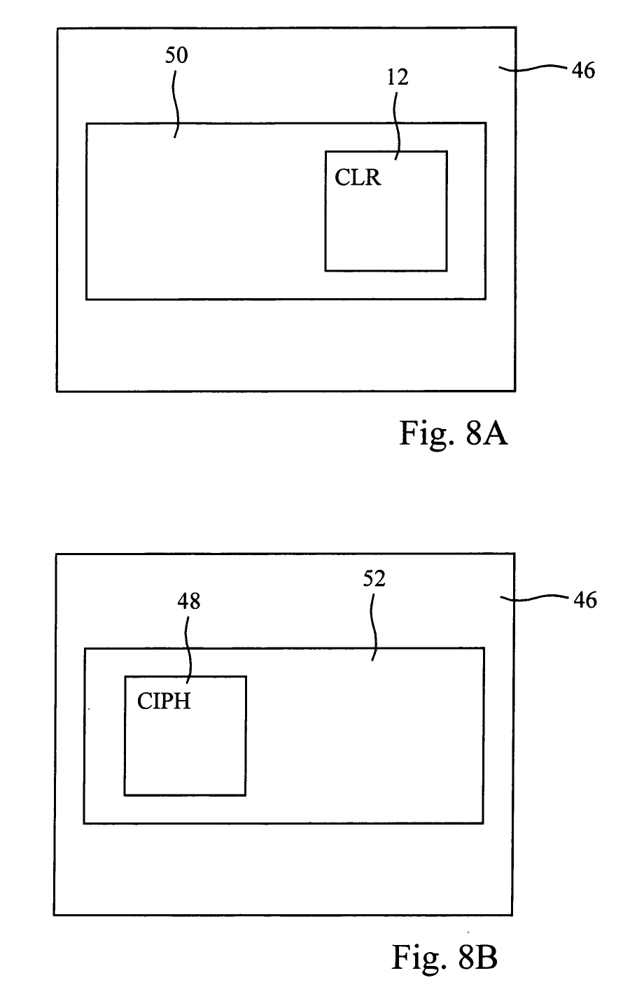

FIG. 8A shows a schematic presentation of the generating module according to FIG. 6 with the un-encoded configuration data stored in the configuration-data-record;

FIG. 8B shows a schematic presentation of the generating module according to FIG. 6, wherein the configuration data to be encoded are stored in a new configuration-data-record; and

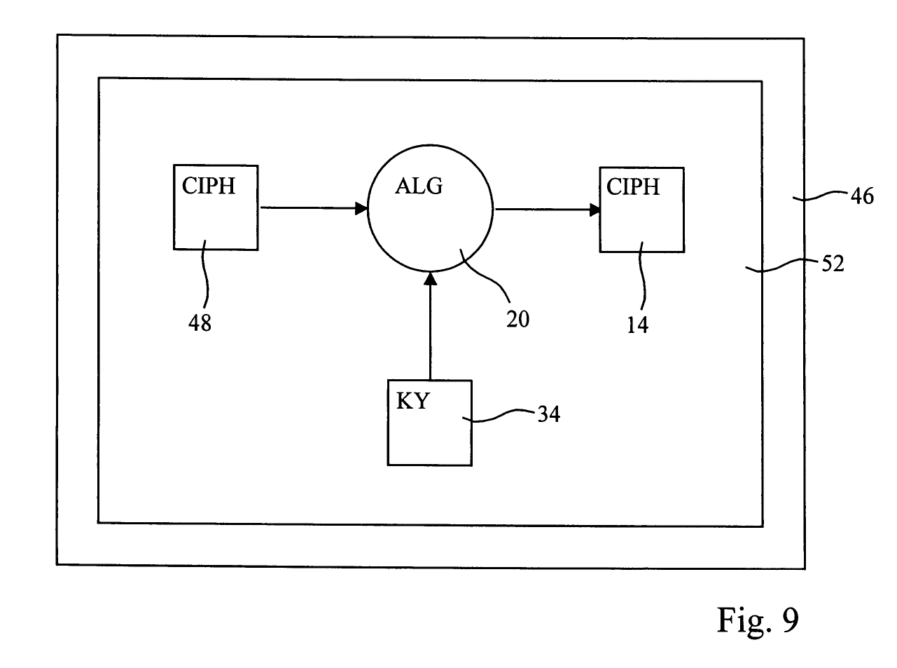

FIG. 9 shows a schematic presentation of the generating module according to FIG. 6, wherein the configuration data to be encoded are encoded by means of an algorithm and a key for the activation of the algorithm.

FIGS. 1 to 5 shows the individual method steps of the method according to the invention for the supply of encoded configuration data to a programmable, integrated logic circuit.

FIG. 1 shows a schematic presentation of a device 2 with a logic circuit 4, which is designed in the exemplary embodiment as a freely programmable logic circuit (FPGA), with a configuration memory device 6, which is connected to the logic circuit 4 via a signal line 8 and a logic-circuit-external loading interface 10 configured in the logic circuit 4. The logic-circuit-external loading interface 10 generates a connection, through which data can be supplied from externally to the logic circuit 4.

The configuration memory device 6 comprises un-encoded configuration data 12 and encoded configuration data 14.

Initially, the un-encoded configuration data 12 are supplied, via a signal line 16 provided in the configuration memory device 6, via the signal line 8 and via the loading interface 10, to the logic circuit 4. In the illustrated exemplary embodiment, the un-encoded configuration data 12 comprise start-up instructions 18, with which the logic circuit 4 is booted, an algorithm 20 for decoding the encoded configuration data 14, commands 22 for the connection of a logic-circuit-internal interface, the function of which is described in detail in the description of FIG. 2, and key instructions 24 for the connection of a logic-circuit-external key interface, which is described in detail in the description for FIG. 3.

FIG. 2 illustrates the device 2 according to FIG. 1 in a status after the loading of the un-encoded configuration data 12 into the logic circuit 4 with the configuration memory device 6 and without the loading interface illustrated in FIG. 1, which is preferably connected only for the supply of the un-encoded configuration data 12 and for the supply of the encoded configuration data 14 to the logic circuit 4.

After the booting of the logic circuit 4, the algorithm 20 for decoding the encoded configuration data is made available in the logic circuit 4 and connected via a logic-circuit-internal signal line 26 to the connected logic-circuit-internal interface 28. The logic-circuit-internal interface 28 is connected by means of the commands 22 provided in the un-encoded configuration data 12. Via the logic-circuit-internal interface 28, the configuration data 14 to be decoded by means of the algorithm 20 are stored in a manner protected logic-circuit-internally from undesired access from outside the logic circuit 4. The logic-circuit-internal interface 28 is expediently connected only for a period for the storage of the configuration data 14 to be decoded. Since the logic circuit 4 has already been booted by means of the start-up instructions 18, that is to say, partially configured, the logic circuit 4 is preferably partially configured and/or reconfigured by means of the configuration data 14 to be decoded.

FIG. 3 shows the device 2 according to FIG. 1 with the logic circuit 4 and the logic-circuit-external key interface 30. The key interface 30 is connected, by means of the key instructions 24, which were loaded together with the un-encoded configuration data 12 from the configuration memory device 6, to the logic circuit for the supply of a key 34 stored in a key memory device 32. The key 34 is supplied, via a signal line 36, the logic-circuit-external key interface 30 and the logic-circuit-internal signal line 38, to the logic circuit 4 for the activation of the algorithm 20. By preference, the key interface 30 is used only for the supply of the key 34. The key interface 30 is expediently connected only for the period of the supply of the key 34.

FIG. 4 shows a schematic presentation of the device 2 according to FIG. 1 in a status after the loading of the key (FIG. 3) via the key interface (FIG. 3). The encoded configuration data 14 are loaded from the configuration memory device 6, via a signal line 40 provided in the configuration memory device 6, via the signal line 8, the loading interface 10 and via a logic-circuit-internal signal line 42, into the logic circuit 4. Within the logic circuit 4, the encoded configuration data 14 are decoded by means of the activated algorithm 20 and stored via the logic-circuit-internal signal line 26 and the logic-circuit-internal interface 28 in the logic circuit 4. The interface 28 is expediently connected only for the period of the storage of the decoded configuration data 14.

Since the encoded configuration data 14 are decoded only logic-circuit-internally, there is no possibility of an access to un-encoded configuration data which are associated with the encoded configuration data 14, in particular during the loading of the encoded configuration data 14 into the logic circuit 4.

FIG. 5 shows the device 2 according to FIG. 1 with a component 44 provided in the logic circuit 4, of which the internal wiring was configured by switching cells, not illustrated in FIG. 5, disposed within the component 44 by means of the decoded configuration data 14, which are stored in the configuration memory device 6 as encoded configuration data 14. By separating the component 44 from the internal interface 28, access from outside the logic circuit via the logic-circuit-external loading interface (FIG. 4) and via the key interface (FIG. 3) can be prevented. The component 44, which can be made accessible only by connecting the logic-circuit-internal interface 28, therefore represents the protected part of the logic circuit 4.

FIGS. 6 to 9 show the individual method steps of the method according to the invention for generating configuration data (12, 14) provided for the programmable, integrated logic circuit (FIGS. 1 to 5).

In this context, FIG. 6 shows a schematic presentation of a generating module 46. The internal wiring of the switching cells of the logic circuit is copied with the generating module 46, which, for reasons of compatibility is preferably supplied by the hardware manufacturer of the logic circuit (FIGS. 1 to 5). Configuration data 48 to be encoded and the un-encoded configuration data 12 are generated by programming switching functions required for the internal wiring of the switching cells. In this context, the configuration data 48 to be encoded expediently comprise switching functions for the partial configuration of the logic circuit (FIGS. 1 to 5), in particular, of the component provided in the logic circuit (FIG. 5).

The un-encoded configuration data 12 comprise the start-up instructions 18, with which the logic circuit is booted, the algorithm 20 for decoding the encoded configuration data 14, the commands 22 for connecting the logic-circuit-internal interface (FIG. 4) and the key instructions 24 for connecting the logic-circuit-external key interface (FIG. 3). The key matching the algorithm 20 is generated separately (FIG. 9). The un-encoded configuration data 12 and the configuration data 48 to be encoded are generated in the generating module 46 and stored in a configuration-data-record 50 provided within the generating module 46.

FIGS. 7, 8A and 8B illustrate the separation of the un-encoded configuration data 12 from the configuration data 48 to be encoded. For this purpose, as presented in FIG. 7, the configuration data 48 to be encoded are deleted in the configuration-data-record 50 of the generating module 46 and inserted into a new configuration-data-record 52 generated within the generating module 46 (FIG. 8B). The un-encoded configuration data 12 remain in the configuration-data-record 50 of the generating module 46 (FIG. 8A).

FIG. 9 shows the encoding of the configuration data 48 to be encoded. For this purpose, the configuration data 48 to be encoded, which are stored in the configuration data-record 52, are encoded with the algorithm 20, which is activated by the key 34 matching the latter and once again stored in the configuration-data-record 52 as encoded configuration data 14. In the exemplary embodiment, the same key 34 is used for the encoding of the configuration data 48 to be encoded and for the decoding of the encoded configuration data 14. It is entirely expedient to use different keys for the encoding and for the decoding, which are generated to match the algorithm 20.

After the generation of the un-encoded configuration data 12 and of the encoded configuration data 14 and of the key 34, these are expediently stored in the configuration memory device (FIG. 1) or in the key memory device preferably provided separately from the configuration memory device (FIG. 3).

The invention is not restricted to the exemplary embodiment presented in the drawings, in particular not to an FPGA based upon RAM and to the generating module for generating the configuration data provided for logic circuit. All of the features described and illustrated in the drawings can be combined with one another as required.

1. Method for supplying encoded configuration data (14) to a programmable, integrated logic circuit (4),
wherein un-encoded configuration data (12) comprising an algorithm (20) are supplied to the logic circuit (4),
and wherein the encoded configuration data (14) are loaded into the logic circuit (4) by means of the algorithm (20) and a key (34), which is supplied to the logic circuit (4) logic-circuit-externally and separately from the encoded configuration data (14) and from the un-encoded configuration data (12), decoded for the activation of the algorithm (20) and stored logic-circuit-internally.

2. Method according to claim 1,
characterised in that
the logic circuit (4) is booted by means of start-up instructions (18), which are deposited in the un-encoded configuration data (12).

3. Method according to claim 1 or 2,
characterised in that
a logic-circuit-external key interface (30) for the supply of the key (34) is connected by means of key instructions (24), which are deposited in the un-encoded configuration data (12).

4. Method according to any one of claims 1 to 3,
characterised in that
the key (34) is provided to the algorithm (20) only for the period of the decoding of the encoded configuration data (14).

5. Method according to any one of claims 1 to 4,
characterised in that
a logic-circuit-internal interface (28) for the storage of the decoded configuration data (14) in the logic circuit (4) is connected by means of commands (22), which are deposited in the un-encoded configuration data (12).

6. Method according to any one of claims 1 to 5,
characterised in that
the logic circuit (4) is at least partially configured with the encoded configuration data (14).

7. Device (2) for the supply of encoded configuration data (14) to a programmable, integrated logic circuit (4), with a loading interface (10), across which the encoded configuration data (14) and un-encoded, configuration data (12) comprising an algorithm (20) for the decoding of the encoded configuration data (14) can be supplied to the logic circuit (4),
a logic-circuit-external key interface (30) for the supply of a key (34) for the activation of the algorithm (20), and
a logic-circuit-internal interface (28), across which the configuration data (14) decoded by means of the algorithm (20) are stored logic-circuit-internally.

8. Device according to claim 7,
characterised by
a configuration memory device (6) for the storage of the encoded configuration data (14) and/or of the un-encoded configuration data (12).

9. Device according to claim 8,
characterised in that
the configuration memory device (6) is designed as a tabular memory, in particular, as a programmable readout memory.

10. Device according to any one of claims 7 to 9,
characterised in that
the un-encoded configuration data (12) comprise start-up instructions (18) for booting the logic circuit (4).

11. Device according to any one of claims 7 to 10,
characterised by
a key memory device (32), in which the key (34) is stored and which can be coupled with the logic-circuit-external key interface (30) for the supply of the key (34).

12. Device according to claim 11,
characterised in that
the key memory device (32) is designed to be deletable.

13. Device according to any one of claims 7 to 12,
characterised in that
the logic circuit (4) is designed as a freely-programmable logic circuit (FPGA).

14. Device according to any one of claims 7 to 13,
characterised in that
the un-coded configuration data (12) comprise key instructions (24) for the connection of the logic-circuit-external key interface (13).

15. Device according to any one of claims 7 to 14,
characterised in that
the un-encoded configuration data (12) comprise commands (22) for the connection of the logic-circuit-internal interface (28).

16. Method for the generation of configuration data (12, 14) provided for a programmable, integrated logic circuit (4),
wherein the configuration data (12, 14) are prepared with a generating module (46) and subdivided into configuration data (48) to be encoded, and un-encoded configuration data (12) comprising an algorithm (20) for the encoding and for the decoding of the configuration data (48) to be encoded,
wherein a key (34) suitable for the activation of the algorithm (20) is determined,
wherein the configuration data (48) to be encoded are encoded by means of the algorithm (20), and
wherein the encoded configuration data and the un-encoded configuration data (12) and the key (34) are stored separately from the encoded configuration data (14) and the un-encoded configuration data (12) logic-circuit-externally.

17. Method according to claim 16, characterised in that the encoded configuration data (14) and/or the un-encoded configuration data (12) are stored in one or more configuration memory devices (6), which are physically separate from the logic circuit (4).

18. Digital storage medium with electronically-readable control signals, which can cooperate in such a manner with the programmable computer or digital signal processor that a method according to any one of claim 1 to 6, 16 or 17 is executed.

19. Computer program with program-code means for the implementation of a method according to any one of claim 1 to 6, 16 or 17, when the computer program is executed in a computer or a digital signal processor.

20. Computer program with program-code means, for the implementation of all of the steps according to any one of claim 1 to 6, 16 or 17, wherein the computer program is stored on a machine-readable medium.

21. Computer-software product with program-code means stored on machine-readable data media, for the implementation of a method according to any one of claim 1 to 6, 16 or 17, wherein the computer-software product is executed in a computer or a digital signal processor.
